(19) United States
(12) Patent Application Publication
(10) Pub. No.: US 2013/0229217 A1
(43) Pub. Date: Sep. 5, 2013

(54) DYNAMIC LATCH AND DATA OUTPUT DEVICE COMPRISING SAME

(71) Applicant: SAMSUNG ELECTRONICS CO., LTD., SUWON-SI (KR)

(72) Inventors: IL-HAN PARK, SUWON-SI (KR); SANG-HYUN JOO, HWASEONG-SI (KR)

(73) Assignee: SAMSUNG ELECTRONICS CO., LTD., SUWON-SI (KR)

(21) Appl. No.: 13/755,034

(22) Filed: Jan. 31, 2013

(30) Foreign Application Priority Data
Mar. 5, 2012 (KR) 10-2012-0022481

(51) Int. Cl. H03K 3/012

(52) U.S. Cl. CPC H03K 3/012
USPC 327/200

(57) ABSTRACT

A dynamic latch comprises a floating node, a storage node, a write transistor connected to the floating node and the storage node and configured to write data of the floating node to the storage node, and a read transistor connected to the floating node and configured to read the data of the storage node.

### CROSS-REFERENCE TO RELATED APPLICATIONS

This application claims priority under 35 U.S.C. §119 to Korean Patent Application No. 10-2012-0022481 filed on Mar. 5, 2012, the subject matter of which is hereby incorporated by reference in its entirety.

### BACKGROUND OF THE INVENTION

The inventive concept relates generally to electronic circuit technologies. More particularly, certain embodiments of the inventive concept relate to a dynamic latch and a data output device comprising the same.

A latch is a digital circuit that can store one or more bits of data. A latch can be classified generally as a static latch or a dynamic latch. A static latch is capable of retaining stored data for an extended period of time without a refresh operation. A dynamic latch, on the other hand, will lose stored data after a period of time if no refresh operation is performed.

A refresh operation typically comprises a first process for writing data stored in a dynamic latch into a separate repository (e.g., a separate latch) and a second process for re-writing the data stored in the separate repository to the dynamic latch. In other words, the refresh process moves data from a dynamic latch to a separate repository and then back to the dynamic latch. Unfortunately, however, the time and power consumption required by this process tend to decrease the efficiency and operating speed of the dynamic latch.

### SUMMARY OF THE INVENTION

In one embodiment of the inventive concept, a dynamic latch comprises a floating node, a storage node, a write transistor connected to the floating node and the storage node and configured to write data of the floating node to the storage node, and a read transistor connected to the floating node and configured to read the data of the storage node.

In another embodiment of the inventive concept, a data output device comprises a dynamic latch configured to store data subject to a refresh operation, and a data compensation unit configured to compensate the data stored in the dynamic latch. The data compensation unit compensates the data stored in the dynamic latch if the dynamic latch is refreshed (2n−1) times and does not compensate the data stored in the dynamic latch if the dynamic latch is refreshed (2n) times, where n is a natural number.

In yet another embodiment of the inventive concept, a dynamic latch comprises a write transistor having a first terminal connected to a floating node and a second terminal connected to a storage node, a read transistor having a first terminal connected to the floating node and a second terminal, and a storage transistor having a first terminal connected to the second terminal of the read transistor, and a second terminal connected to a reference voltage, and a gate connected to the storage node.

These and other embodiments can potentially improve the efficiency of refresh operations in dynamic latches by eliminating a need to backup and then rewrite stored data.

### BRIEF DESCRIPTION OF THE DRAWINGS

The drawings illustrate selected embodiments of the inventive concept. In the drawings, like reference numbers indicate like features, and the relative dimensions of certain features may be exaggerated for clarity of illustration.

FIG. 1 is a circuit diagram of a dynamic latch according to an embodiment of the inventive concept.

FIG. 2 is a diagram illustrating respective sizes of a read transistor, a write transistor, and a storage transistor shown in FIG. 1.

FIG. 3 is a timing diagram illustrating a refresh operation of a dynamic latch according to an embodiment of the inventive concept.

FIG. 4 is a timing diagram illustrating a refresh operation of a dynamic latch according to another embodiment of the inventive concept.

FIG. 5 is a circuit diagram of a dynamic latch according to another embodiment of the inventive concept.

FIG. 6 is a block diagram of a data output device according to an embodiment of the inventive concept.

FIG. 7 is a block diagram of a data compensation unit shown in FIG. 6.

FIG. 8 is a block diagram of a data output device according to another embodiment of the inventive concept.

FIG. 9 is a block diagram of a data compensation unit shown in FIG. 8.

FIG. 10 is a block diagram of a memory system according to an embodiment of the inventive concept.

FIG. 11 is a block diagram of a variation of the memory system shown in FIG. 10.

FIG. 12 is a block diagram of a computing system incorporating the memory system of FIG. 11.

### DETAILED DESCRIPTION

Embodiments of the inventive concept are described below with reference to the accompanying drawings. These embodiments are presented as teaching examples and should not be construed to limit the scope of the inventive concept.

In the description that follows, where a feature is referred to as being “on” or “connected to” another feature, it can be directly on or connected to the other feature or intervening features may be present. In contrast, where a feature is referred to as being “directly on” or “directly connected to” another feature, there are no intervening features present. As used herein, the term “and/or” indicates any and all combinations of one or more of the associated listed items.

The use of the terms “a” and “an” and “the” and similar referents are to be construed to cover both the singular and the plural, unless otherwise indicated by context. Terms such as “comprising,” “having,” “including,” “containing,” etc., are to be construed as open-ended terms unless otherwise noted.

Although the terms first, second, etc. may be used to describe various features, the described features are not to be limited by these terms. Rather, these terms are used merely to distinguish between different features. Thus, for example, a first feature could be termed a second feature, and vice versa, without materially changing the meaning of the description.

Unless defined otherwise, all technical and scientific terms used herein have the same meaning as commonly understood by one of ordinary skill in the art. The use of any and all examples or example terms is intended merely to better illuminate the inventive concept and is not a limitation on the scope of the inventive concept unless otherwise specified. Further, unless defined otherwise, terms such as those defined in common dictionaries should not be interpreted in an overly formal manner.

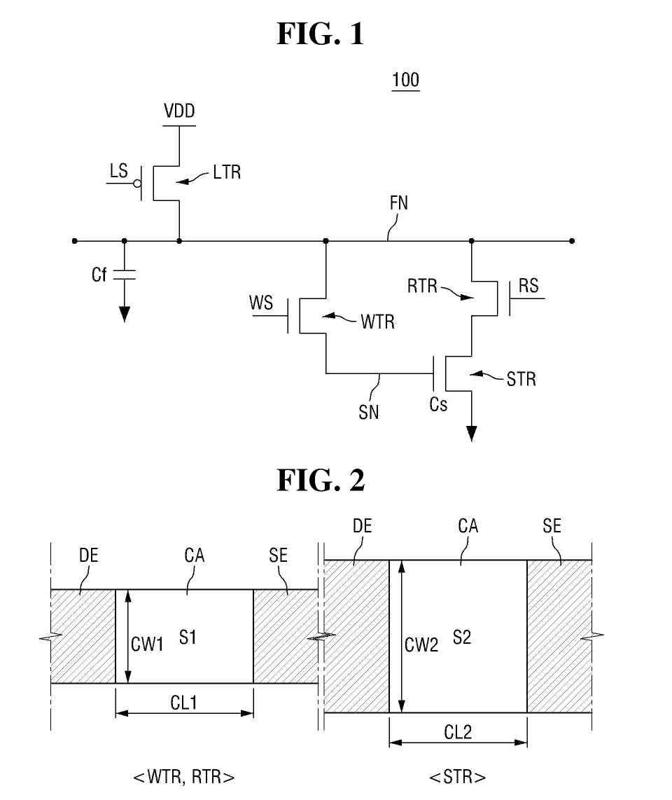

FIG. 1 is a circuit diagram of a dynamic latch 100 according to an embodiment of the inventive concept, and FIG. 2 is a diagram illustrating respective sizes of a read transistor RTR, a write transistor WTR, and a storage transistor STR shown in FIG. 1.

Referring to FIG. 1, dynamic latch 100 comprises a floating node FN, a storage node SN, write transistor WTR, and read transistor RTR.

Write transistor WTR and read transistor RTR share floating node FN as shown in FIG. 1. That is, write transistor WTR is directly connected to floating node FN, and read transistor RTR is also directly connected to floating node FN. More specifically, a first electrode (e.g., a drain electrode) of write transistor WTR is directly connected to floating node FN, and a first electrode (e.g., a drain electrode) of read transistor RTR is directly connected to floating node FN.

A second electrode (e.g., a source electrode) of write transistor WTR is connected to storage node SN. Write transistor WTR writes data of floating node FN to storage node SN in response to a write signal WS transmitted to a gate electrode thereof. Specifically, write transistor WTR charges storage node SN with some electric charges of floating node FN in response to write signal WS transmitted to the gate electrode thereof. This operation of write transistor WTR is described in further detail below.

In some embodiments, storage node SN is implemented using a gate capacitor of a transistor. For example, storage node SN may be implemented using a gate capacitor of storage transistor STR which has a gate electrode connected to write transistor WTR and a first electrode (e.g., a drain electrode) connected to read transistor RTR. A second electrode (e.g., a source electrode) of storage transistor STR is connected to a ground terminal as shown in the drawing.

A second electrode (e.g., a source electrode) of read transistor RTR is connected to the first electrode (e.g., a drain electrode) of storage transistor STR. Read transistor RTR reads data of storage node SN. Specifically, where a read signal RS is transmitted to the gate electrode of read transistor RTR, read transistor RTR reads data of storage node SN by changing a level of electric charge in floating node FN to a level of electric charges in storage node SN. This operation of read transistor RTR will also be described in further detail below.

Floating node FN may also be connected to a charge source which supplies charges to floating node FN. In some embodiments, the charge source may be a load transistor LTR as shown in the drawing. Specifically, load transistor LTR may have a first electrode (e.g., a source electrode) connected to a power supply terminal VDD and a second electrode (e.g., a drain electrode) connected to floating node FN. Load transistor LTR supplies charges received from power supply terminal VDD to floating node FN in response to a load signal LS transmitted to a gate electrode thereof.

In some embodiments, write transistor WTR, read transistor RTR, and storage transistor STR are all implemented as n-channel metal oxide semiconductor (NMOS) transistors. In this case, load transistor LTR may be implemented as a p-channel metal oxide semiconductor (PMOS) transistor.

In some other embodiments, the size of storage transistor STR may be different from the size of write transistor WTR and the size of read transistor RTR. Specifically, storage transistor STR may be larger than write transistor WTR and read transistor RTR. Examples of these size differences are illustrated in FIG. 2. In particular, FIG. 2 shows a source electrode SE and a drain electrode DE of storage transistor STR and a source electrode SE and a drain electrode DE of write transistor WTR or read transistor RTR. The gate electrode (not shown) of each transistor STR, WTR or RTR is formed on source electrode SE and drain electrode DE to overlap source electrode SE and drain electrode DE. However, the gate electrode is omitted from the drawing for ease of description.

Referring to FIG. 2, storage transistor STR is larger than write transistor WTR and read transistor RTR. Specifically, source electrode SE of storage transistor STR is larger than source electrode SE of each of write transistor WTR and read transistor RTR, and drain electrode DE of storage transistor STR may be larger than drain electrode DE of each of write transistor WTR and read transistor RTR.

A cross-sectional area of a channel region CA surrounded by source electrode SE and drain electrode DE is larger in storage transistor STR than in write transistor WTR and read transistor RTR. Specifically, a cross-sectional area S2 of a channel region of storage transistor STR may be larger than a cross-sectional area S1 of a channel region of each of write transistor WTR and read transistor RTR.

The reason why cross-sectional area S2 of the channel region of storage transistor STR is larger than cross-sectional area S1 of the channel region of each of write transistor WTR and read transistor RTR is that a channel length CL2 of storage transistor STR is greater than a channel length CL1 of each of write transistor WTR and read transistor RTR or that a channel width CW2 of storage transistor STR is greater than a channel width CL2 of each of write transistor WTR and read transistor RTR. In particular, in some embodiment of the inventive concept, channel length CL2 and channel width CW2 of storage transistor STR may all be greater than channel length CL1 and channel width CW1 of each of write transistor WTR and read transistor RTR.

In a write operation of dynamic latch 100, write transistor WTR is turned on. Then, write transistor WTR writes data of floating node FN to storage node SN. Specifically, where electric charges are supplied to floating node FN from power supply terminal VDD because load transistor LTR is turned on, high-level data (e.g., 1) is stored in floating node FN. Here, if write transistor WTR is turned on, storage node SN and floating node FN share electric charges due to a capacitance difference (Cs and Cf) between them. That is, some of the electric charges in floating node FN are charged in storage node SN. Accordingly, the high-level data (e.g., 1) is written to storage node SN.

Where no electric charges are supplied to floating node FN from power supply terminal VDD because load transistor LTR is turned off, low-level data (e.g., 0) is stored in floating node FN. Here, if write transistor WTR is turned on, the low-level data (e.g., 0) of floating node FN is also written to storage node SN. Certain aspects of the write operation are illustrated by the following Table 1.

TABLE 1

| Floating node | Write transistor | Storage node |
|---|---|---|
| 0 | ON | 0 |
| 1 | ON | 1 |

As indicated by Table 1, where write transistor WTR is turned on by write signal WS, data is written from floating node FN to storage node SN.

In a read operation of dynamic latch 100, read transistor RTR is turned on by read signal RS and reads data of storage node SN. To this end, load transistor LTR is turned on to supply electric charges to floating node FN. Where electric charges are supplied to floating node FN, high-level data (e.g., 1) is stored in floating node FN.

Here, if high-level data (e.g., 1) is stored in storage node SN, storage transistor STR is turned on. In this case, if read transistor RTR is turned on by read signal RS, floating node FN is connected to the ground terminal. Accordingly, all of the electric charges in floating node FN flow to the ground terminal. Thus, no electric charges remain in floating node FN. Therefore, low-level data (e.g., 0) is stored in floating node FN. Consequently, if data read from floating node FN by read transistor RTR after turned on is low-level data (e.g., 0), it can be understood that high-level data (e.g., 1) is stored in storage node SN.

Conversely, if low-level data (e.g., 0) is stored in storage node SN, storage transistor STR is turned off. In this case, if read transistor RTR is turned on by read signal RS, floating node FN is not connected to the ground terminal but remains floating. Therefore, the high-level data (e.g., 1) is still stored in floating node FN. Consequently, if data read from floating node FN by read transistor RTR after turned on is high-level data (e.g., 0), it can be understood that low-level data (e.g., 0) is stored in storage node SN. Certain aspects of the read operation are illustrated by the following Table 2.

TABLE 2

| | | | | Read data |
|---|---|---|---|---|
| Initial floating | Storage | Read | | (Opposite to data |
| node | node | transistor | Floating node | of floating node) |
| 1 | 1 | ON | 0 | 1 |
| 1 | 0 | ON | 1 | 0 |

As illustrated by Table 2, where read transistor RTR is turned on by read signal RS, it changes the level of electric charge in floating node FN to the level of electric charge in storage node SN. In so doing, read transistor RTR can read whether data stored in storage node SN is high-level data or low-level data.

Here, where high-level data (e.g., 1) is stored in storage node SN, storage node SN may eventually lose the high-level data because electric charges flow out of storage node SN over time. Therefore, it is necessary to refresh data stored in storage node SN periodically.

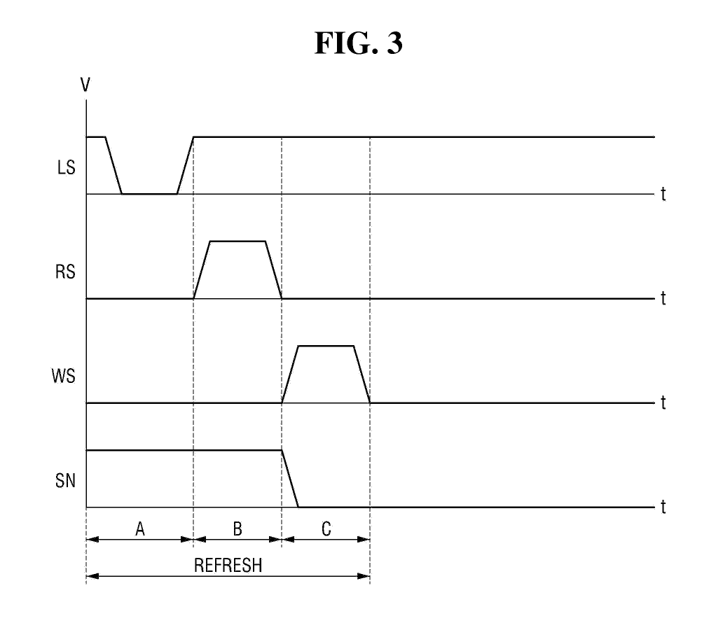

FIG. 3 is a timing diagram illustrating a refresh operation of dynamic latch 100 according to an embodiment of the inventive concept. This refresh operation will be described below with reference to FIGS. 1 and 3.

Referring to FIGS. 1 and 3, load signal LS is transmitted to load transistor LTR to turn on load transistor LTR. Accordingly, high-level data (e.g., 1) is stored in floating node FN (section A). Here, electric charges are supplied to floating node FN from power supply terminal VDD. Thus, the high-level data (e.g., 1) is stored in floating node FN.

Next, read signal RS is transmitted to read transistor RTR to turn on read transistor RTR. Accordingly, the high-level data of floating node FN is changed to low-level data (e.g., 0) (section B). Changing data of floating node FN has been described above, and thus additional description thereof will be omitted.

Next, write signal WS is transmitted to write transistor WTR, thereby turning on write transistor WTR. Accordingly, the low-level data (e.g., 0) stored in floating node FN is written to storage node SN (section C). Certain aspects of the above process are illustrated by the following Table 3.

TABLE 3

| | Load | Read | Write | | Storage |
|---|---|---|---|---|---|
| Section | transistor | transistor | transistor | Floating node | node |
| A | ON | OFF | OFF | 1 | 1 |
| B | OFF | ON | OFF | 0 | 1 |
| C | OFF | OFF | ON | 0 | 0 |

Whenever the refresh operation is performed as described above, the level of data stored in storage node SN is changed (for example, from 0 to 1 or from 1 to 0). Therefore, data stored in storage node SN needs to be compensated by taking the data-level change into consideration. Further discussion of data compensation is provided below. In addition, data stored in storage node SN can also be refreshed without taking data compensation into consideration.

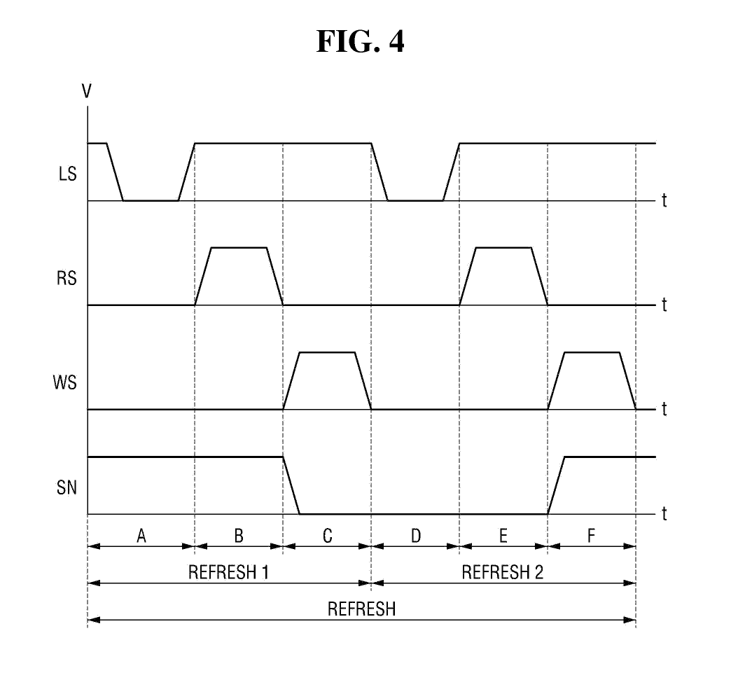

FIG. 4 is a timing diagram illustrating a refresh operation of dynamic latch 100 according to another embodiment of the inventive concept. This refresh operation will be described below with reference to FIGS. 1 and 4.

Referring to FIGS. 1 and 4, the refresh operation of FIG. 3 is performed twice. In other words, the above-described refresh operation is performed twice as a first refresh refresh1 and a second refresh refresh2.

In the first refresh refresh1, load signal LS is transmitted to load transistor LTR to turn on load transistor LTR. Accordingly, high-level data (e.g., 1) is stored in floating node FN (section A). Then, read signal RS is transmitted to read transistor RTR to turn on read transistor RTR. Accordingly, the high-level data of floating node FN is changed to low-level data (e.g., 0) (section B). Then, write signal WS is transmitted to write transistor WTR to turn on write transistor WTR. Accordingly, the low-level data (e.g., 0) stored in floating node FN is written to storage node SN (section C). This process has been described above, and thus a repetitive description thereof will be omitted.

In the second refresh refresh2, load signal LS is transmitted to load transistor LTR to turn on load transistor LTR. Accordingly, high-level data (e.g., 1) is stored in floating node FN (section D). Then, read signal RS is transmitted to read transistor RTR to turn on read transistor RTR. In this case, because the low-level data (e.g., 0) is stored in storage node SN, the high-level data (e.g., 1) stored in floating node FN remains unchanged (section E). Finally, write signal WS is transmitted to write transistor WTR to turn on write transistor WTR. Accordingly, the high-level data (e.g., 1) stored in floating node FN is written to storage node SN (section F). Certain aspects of the above process are illustrated by the following Table 4.

TABLE 4

| | Load | Read | Write | | Storage |
|---|---|---|---|---|---|
| Section | transistor | transistor | transistor | Floating node | node |
| A | ON | OFF | OFF | 1 | 1 |
| B | OFF | ON | OFF | 0 | 1 |
| C | OFF | OFF | ON | 0 | 0 |
| D | ON | OFF | OFF | 1 | 0 |
| E | OFF | ON | OFF | 1 | 0 |
| F | OFF | OFF | ON | 1 | 1 |

In the refresh operation of FIG. 4, the level of data stored in storage node SN is changed not in every refresh. Therefore, there is no need to compensate the data stored in storage node SN.

As indicated by the foregoing, the refresh operation of dynamic latch 100 may omit a process of writing data stored in storage node SN to a separate repository (e.g., another latch) and reading the written data. This can be accomplished by exchanging data only between storage node SN and floating node FN. Therefore, the time and power consumption required to exchange data with a separate repository (e.g., a separate latch) are sharply reduced, leading to the improvement of the efficiency and operating speed of dynamic latch 100.

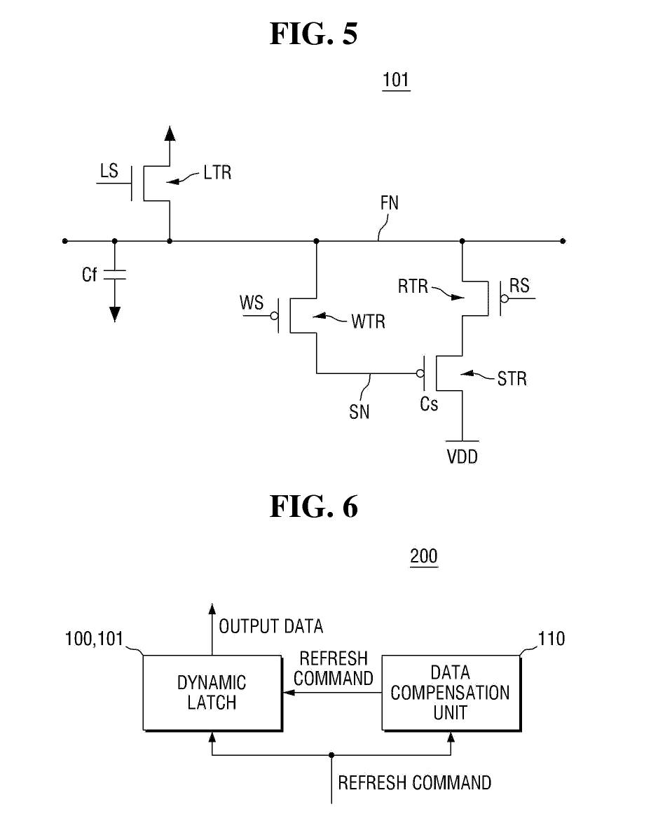

FIG. 5 is a circuit diagram of a dynamic latch 101 according to another embodiment of the inventive concept. Dynamic latch 101 has several features similar to those of dynamic latch 100, and a repetitive description of similar features will be omitted in order to avoid redundancy.

Referring to FIG. 5, dynamic latch 101 comprises a floating node FN, a storage node SN, a write transistor WTR, and a read transistor RTR. Write transistor WTR and read transistor RTR are all implemented by PMOS transistors. In addition, a storage transistor STR connected to write transistor WTR is also implemented by a PMOS transistor. Where all of write transistor WTR, read transistor RTR, and storage transistor STR are implemented as PMOS transistors, a load transistor LTR may be implemented as an NMOS transistor.

Specifically, load transistor LTR may connect floating node FN to a ground terminal in response to a load signal LS transmitted to a gate electrode thereof. A second electrode (e.g., a source electrode) of storage transistor STR is connected to a power supply terminal VDD.

The operation of dynamic latch 101 can be inferred from the above-described operations of dynamic latch 100, so a repetitive description thereof will be omitted.

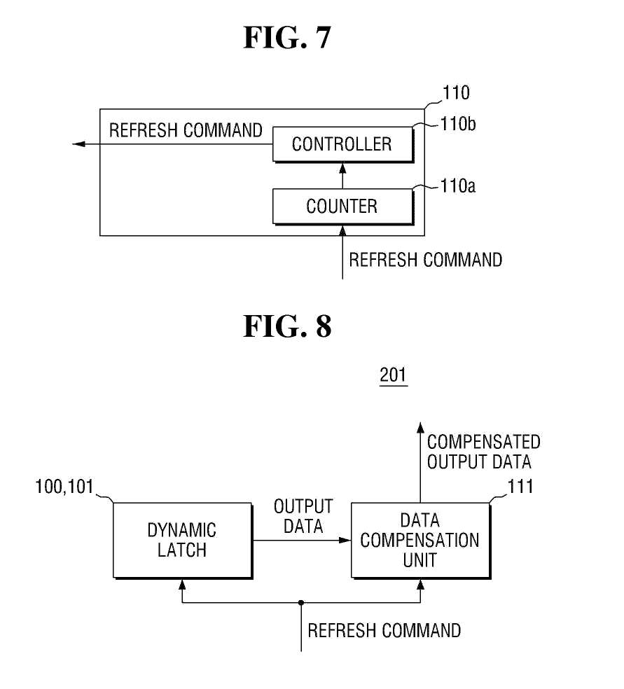

FIG. 6 is a block diagram of a data output device 200 according to an embodiment of the inventive concept, and FIG. 7 is a detailed conceptual block diagram of a data compensation unit 110 shown in FIG. 6.

In the description that follows, the term ‘unit’ may refer to, for instance, a software or hardware component, such as a field programmable gate array (FPGA) or Application Specific Integrated Circuit (ASIC). A unit may be configured to reside on the addressable storage medium and configured to execute on one or more processors. Thus, a unit may comprise, e.g., components, such as software components, object-oriented software components, class components and task components, processes, functions, attributes, procedures, subroutines, segments of program code, drivers, firmware, microcode, circuitry, data, databases, data structures, tables, arrays, and variables. The functionality provided by the components and units may be combined into fewer components and units or further separated into additional components and units.

Referring to FIG. 6, data output device 200 comprises a dynamic latch 100 or 101 and data compensation unit 110.

Where high-level data (e.g., 1) is stored in dynamic latch 100 or 101, if dynamic latch 100 or 101 is refreshed (2n−1) times (where n is a natural number) in response to a refresh command, low-level data (e.g., 0) is stored in dynamic latch 100 or 101. That is, the level of data stored in dynamic latch 100 or 101 is changed.

Where the high-level data (e.g., 1) is stored in dynamic latch 100 or 101, if dynamic latch 100 or 101 is refreshed (2n) times in response to a refresh command, the high-level data (e.g., 1) stored in dynamic latch 100 or 101 remains unchanged. That is, the level of data stored in dynamic latch 100 or 101 is not changed.

Data compensation unit 110 compensates data stored in dynamic latch 100 or 101. Specifically, data compensation unit 110 compensates data stored in dynamic latch 100 or 101 if dynamic latch 100 or 101 is refreshed (2n−1) times and may not compensate the data stored in dynamic latch 100 or 101 if dynamic latch 100 or 101 is refreshed (2n) times.

More specifically, if dynamic latch 100 or 101 is refreshed (2n−1) times, a level of data stored in dynamic latch 100 or 101 is different from an initial level of the data. Therefore, data compensation unit 110 may send a refresh command to dynamic latch 100 or 101 in order to refresh dynamic latch 100 or 101 once more. If dynamic latch 100 or 101 is refreshed once more, it will eventually be refreshed (2n) times. Therefore, a level of the data output from dynamic latch 100 or 101 is the same as the initial level of the data stored in dynamic latch 100 or 101.

Where dynamic latch 100 or 101 is refreshed (2n) times, a level of data stored in dynamic latch 100 or 101 is the same as an initial level of the data. In this case, data compensation unit 110 does not send a refresh command to dynamic latch 100 or 101. Therefore, a level of the data output from dynamic latch 100 or 101 is the same as the initial level of the data stored in dynamic latch 100 or 101.

Referring to FIG. 7, data compensation unit 110 comprises a counter 110a that counts the number of refreshes of dynamic latch 100 or 101 and a controller 110b that sends a refresh command to dynamic latch 100 or 101 based on the counting result. In FIG. 7, counter 110a and controller 110b are separated for ease of description, but these features could also be integrated as desired.

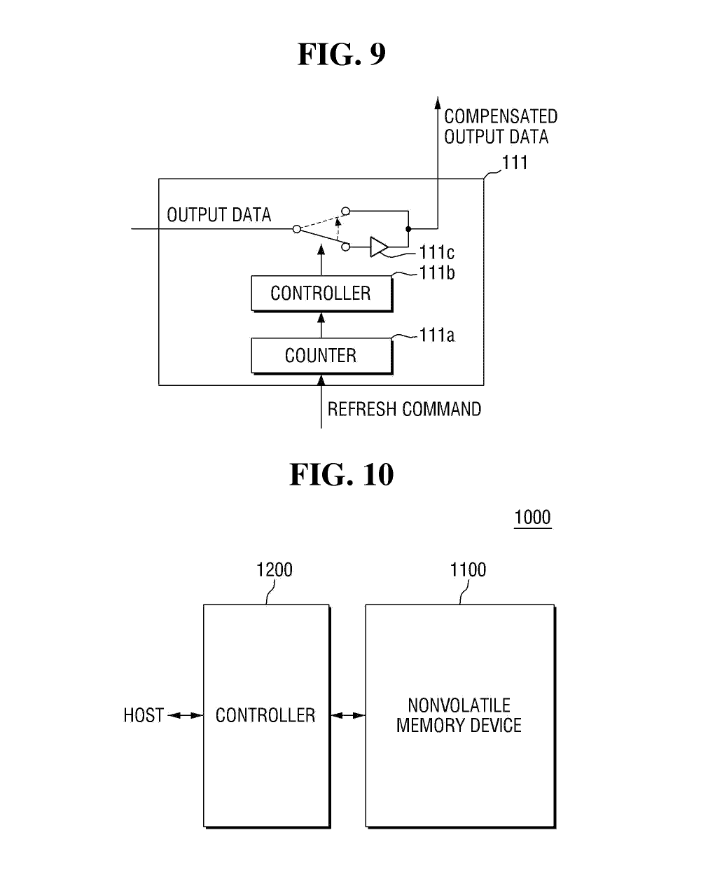

FIG. 8 is a block diagram of a data output device 201 according to another embodiment of the inventive concept, and FIG. 9 is a detailed conceptual block diagram of a data compensation unit 111 shown in FIG. 8.

Referring to FIG. 8, data output device 201 comprises a dynamic latch 100 or 101 and data compensation unit 111.

Similar to embodiment of FIGS. 6 and 7, dynamic latch 100 or 101 may be a latch in which a level of data stored in a storage node SN (see FIG. 1) is changed whenever a refresh operation is performed in response to a refresh command.

Data compensation unit 111 compensates data stored in dynamic latch 100 or 101 and outputs the compensated data. Where dynamic latch 100 or 101 is refreshed (2n−1) times, data compensation unit 111 may compensate data stored in dynamic latch 100 or 101 and output the compensated data. Where dynamic latch 100 or 101 is refreshed (2n) times, data compensation unit 111 may not compensate the data stored in dynamic latch 100 or 101 and output the data as it is.

Where dynamic latch 100 or 101 is refreshed (2n−1) times, a level of data stored in dynamic latch 100 or 101 is different from an initial level of the data. In this case, data compensation unit 111 receives the data from dynamic latch 100 or 101, compensates the received data by changing the level of the received data, and outputs the compensated data. Therefore, a level of the compensated data may be the same as the initial level of the data stored in dynamic latch 100 or 101.

Where dynamic latch 100 or 101 is refreshed (2n) times, a level of the data stored in dynamic latch 100 or 101 is the same as the initial level of the data. Therefore, data compensation unit 111 receives the data output from dynamic latch 100 or 101 and outputs the received data without compensating the received data.

Referring to FIG. 9, data compensation unit 111 comprises a counter 111a that counts the number of refreshes of dynamic latch 100 or 101, a controller 1110b that controls an internal switch based on the counting result, and an inverter 111c which changes a level of data output from dynamic latch 100 or 101.

Counter 111a and controller 111b can be integrated as desired, and the internal switch and inverter 111c can be implemented using a plurality of transistors.

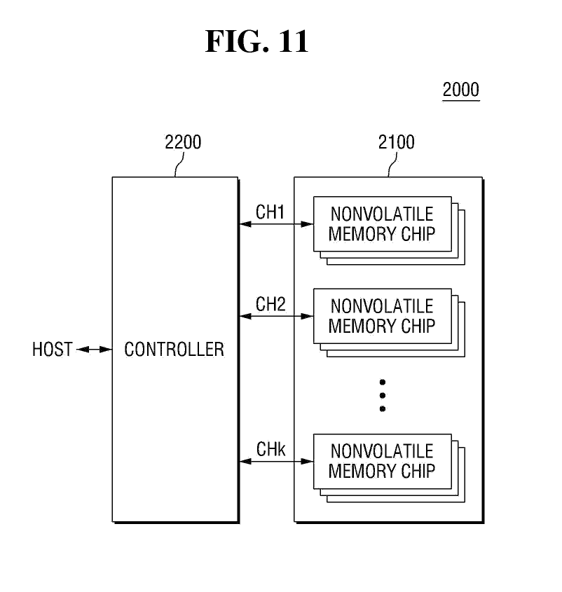

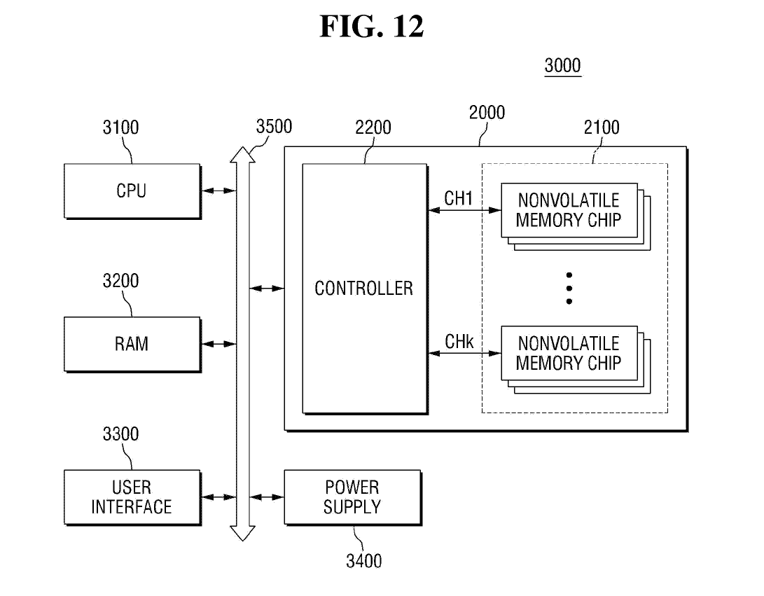

FIG. 10 is a block diagram of a memory system 1000 according to an embodiment of the inventive concept, FIG. 11 is a block diagram of a memory system 2000, which is a variation of memory system 1000, and FIG. 12 is a block diagram of a computing system 3000 incorporating memory system 2000.

Referring to FIG. 10, memory system 1000 comprises a nonvolatile memory device 1100 and a controller 1200. Nonvolatile memory device 1100 comprises dynamic latch 100 (see FIG. 1) or 101 (see FIG. 5) and/or data output device 200 (see FIG. 6) or 201 (see FIG. 8). Controller 1200 is connected to a host and nonvolatile memory device 1100. Controller 1200 is configured to access nonvolatile memory device 1100 in response to a request from the host. For example, controller 1200 may be configured to control read/write/erase/background operations of nonvolatile memory device 1100. Controller 1200 is further configured to provide an interface between nonvolatile memory device 1100 and the host. Controller 1200 may be configured to drive firmware for controlling nonvolatile memory device 1100.

Controller 1200 may further comprise other features such as a random access memory (RAM), a processing unit, a host interface, and a memory interface. The RAM can be used as at least one of an operation memory of the processing unit, a cache memory between nonvolatile memory device 1100 and the host, and a buffer memory between nonvolatile memory device 1100 and the host. The processing unit controls overall operations of controller 1200.

The host interface implements a protocol for data exchange between host and controller 1200. For example, controller 1200 may be configured to communicate with an external device (e.g., the host) using at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol. The memory interface may interface with nonvolatile memory device 1100. For example, the memory interface comprises a NAND interface or a NOR interface.

Memory system 1000 may further comprise an error correction block. The error correction block may be configured to detect and correct an error in data read from nonvolatile memory device 1100 by using an error correction code (ECC). For example, the error correction block may be provided as a component of controller 1200. The error correction block can also be provided as a component of nonvolatile memory device 1100.

Controller 1200 and nonvolatile memory device 1100 may be integrated into one semiconductor device. As an example, controller 1200 and nonvolatile memory device 1100 may be integrated into one semiconductor device to comprise a memory card. For example, controller 1200 and nonvolatile memory device 1100 may be integrated into one semiconductor device to comprise a personal computer (PC) card (e.g., Personal Computer Memory Card International Association (PCMCIA)), a compact flash card (CF), a smart media card (SM/SMC), a memory stick, a multimedia card (e.g., MMC, RS-MMC and MMCmicro), a SD card (e.g., SD, miniSD, microSD, and SDHC), or a universal flash storage (UFS).

In some embodiments, controller 1200 and nonvolatile memory device 1100 may be integrated into one semiconductor device to form a solid state drive (SSD). The SSD comprises a storage device which stores data in a semiconductor memory. Where memory system 1000 is used as an SSD, the operation speed of the host connected to memory system 1000 may increase significantly.

In some embodiments, memory system 1000 may be integrated with any of various electronic devices such as computers, ultra-mobile PCs (UMPCs), workstations, net-books, personal digital assistants (PDAs), portable computers, web tablets, wireless phones, mobile phones, smart phones, e-books, portable multimedia players (PMPs), portable game devices, navigation devices, black boxes, digital cameras, three-dimensional televisions, digital audio recorders, digital audio players, digital picture recorders, digital picture players, digital video recorders, digital video players, devices capable of transmitting/receiving information in wireless environments, one of various electronic devices constituting a home network, one of various electronic devices constituting a computer network, one of various electronic devices constituting a telematics network, a radio frequency identification (RFID) device, or one of various components constituting a computing system.

In some embodiments, nonvolatile memory device 1100 or memory system 1000 may be mounted in various types of packages. Examples of packages or package types that may be used in conjunction with nonvolatile memory device 1100 or memory system 1000 include Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

Referring to FIG. 11, memory system 2000 comprises a nonvolatile memory device 2100 and a controller 2200. Nonvolatile memory device 2100 comprises a plurality of nonvolatile memory chips. The nonvolatile memory chips form multiple memory chip groups. Each of the memory chip groups has a common channel for communication with controller 2200. For example, it is illustrated in FIG. 11 that the nonvolatile memory chips communicate with controller 2200 through first through k^{th} channels CH1 through CHk.

In FIG. 11, a plurality of nonvolatile memory chips are connected to one channel. However, memory system 2000 can be modified such that one nonvolatile memory chip is connected to one channel.

Referring to FIG. 12, computing system 3000 comprises a central processing unit (CPU) 3100, a RAM 3200, a user interface 3300, a power supply 3400, and a memory system 2000.

Memory system 2000 is electrically connected through a system bus 3500 to CPU 3100, RAM 3200, user interface 3300, and power supply 3400. Data provided through user interface 3300 or processed by CPU 3100 is stored in memory system 2000.

In FIG. 12, nonvolatile memory device 2100 is connected to system bus 3500 through controller 2200. However, nonvolatile memory device 2100 can also be connected directly to system bus 3500.

Although computing system 3000 is shown in FIG. 12 with memory system 2000, it could alternatively include memory system 1000 of FIG. 10. Computing system 3000 could also include both of memory systems 1000 and 2000.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

1. A dynamic latch, comprising:
a floating node;
a storage node;
a write transistor connected to the floating node and the storage node and configured to write data of the floating node to the storage node; and
a read transistor connected to the floating node and configured to read the data of the storage node.

2. The dynamic latch of claim 1, wherein the write transistor is connected directly to the floating node.

3. The dynamic latch of claim 2, wherein the read transistor is connected directly to the floating node.

4. The dynamic latch of claim 1, further comprising a storage transistor comprising a gate electrode connected to the write transistor and a first electrode connected to the read transistor, wherein the storage node is a gate capacitor of the storage transistor.

5. The dynamic latch of claim 4, wherein each of the write transistor, the read transistor, and the storage transistor comprise an n-channel metal oxide semiconductor (NMOS) transistor, and a second electrode of the storage transistor is connected to a ground terminal.

6. The dynamic latch of claim 4, wherein each of the write transistor, the read transistor, and the storage transistor comprises a p-channel metal oxide semiconductor (PMOS) transistor, and the second electrode of the storage transistor is connected to a power supply terminal.

7. The dynamic latch of claim 4, wherein a size of the storage transistor is different from respective sizes of the write transistor and the read transistor.

8. The dynamic latch of claim 7, wherein the storage transistor is larger than the write transistor and the read transistor.

9. The dynamic latch of claim 4, wherein a cross-sectional area of a channel region of the storage transistor is greater than a cross-sectional area of a channel region of each of the write transistor and the read transistor.

10. The dynamic latch of claim 1, wherein the data comprises first-level data and second-level data that is different from the first-level data, and the first-level data written to the storage node is changed to the second-level data by a first refresh.

11. The dynamic latch of claim 10, wherein the second-level data written to the storage node by the first refresh is changed to the first-level data by a second refresh performed after the first refresh.

12-15. (canceled)

16. A dynamic latch, comprising:
a write transistor having a first terminal connected to a floating node and a second terminal connected to a storage node;
a read transistor having a first terminal connected to the floating node and a second terminal; and
a storage transistor having a first terminal connected to the second terminal of the read transistor, and a second terminal connected to a first reference voltage, and a gate connected to the storage node.

17. The dynamic latch of claim 16, further comprising a charge source configured to supply charge to the floating node in response to a load signal.

18. The dynamic latch of claim 17, wherein the charge source comprises a load transistor connected between a second reference voltage and the floating node and configured to supply the second reference voltage to the floating node in response to the load signal.

19. The dynamic latch of claim 18, wherein the first reference voltage is ground, the second reference voltage is a power supply voltage, the load transistor is a positive metal oxide semiconductor (PMOS) transistor, and the write transistor, the read transistor, and the storage transistor are all negative metal oxide semiconductor (NMOS) transistors.

20. The dynamic latch of claim 18, wherein the first reference voltage is a power supply voltage, the second reference voltage is ground, the load transistor is a negative metal oxide semiconductor (NMOS) transistor, and the write transistor, the read transistor, and the storage transistor are all positive metal oxide semiconductor (PMOS) transistors.
